(19) United States
(12) Patent Application Publication
(10) Pub. No.: US 2010/0200774 A1
(43) Pub. Date: Aug. 12, 2010

(54) MULTI-SEQUENCE FILM DEPOSITION AND GROWTH USING GAS CLUSTER ION BEAM PROCESSING

(75) Inventors: Edmund Burke, West Newbury, MA (US); John J. Hautala, Beverly, MA (US); Michael Graf, Belmont, MA (US)

Correspondence Address: WOOD, HERRON & EVANS, LLP (TOKYO ELECTRON), 2700 CAREW TOWER, 441 VINE STREET, CINCINNATI, OH, 45202, US

(73) Assignee: TEL Epion Inc., Billerica, MA (US)

(21) Appl. No.: 12/367,757

(22) Filed: Feb. 9, 2009

(51) Int. Cl. H01J 37/08

(52) U.S. Cl. 250/492.21

(57) ABSTRACT

A method of forming a thin film on a substrate is described. The method comprises depositing a first material layer on a substrate using a first gas cluster ion beam (GCIB), the first material layer comprising a first atomic constituent, and growing a second material layer from at least a surface portion of the first material layer by introducing a second atomic constituent using a second GCIB, the second material layer comprising a reaction product of the first and second atomic constituents.

### BACKGROUND OF THE INVENTION

1. Field of Invention

The invention relates to a method for thin film formation on a substrate using gas cluster ion beam (GCIB) processing.

2. Description of Related Art

Gas cluster ion beams (GCIB's) are used for etching, cleaning, smoothing, and forming thin films. For purposes of this discussion, gas clusters are nano-sized aggregates of materials that are gaseous under conditions of standard temperature and pressure. Such gas clusters may consist of aggregates including a few to several thousand molecules, or more, that are loosely bound together. The gas clusters can be ionized by electron bombardment, which permits the gas clusters to be formed into directed beams of controllable energy. Such cluster ions each typically carry positive charges given by the product of the magnitude of the electron charge and an integer greater than or equal to one that represents the charge state of the cluster ion.

The larger sized cluster ions are often the most useful because of their ability to carry substantial energy per cluster ion, while yet having only modest energy per individual molecule. The ion clusters disintegrate on impact with the substrate. Each individual molecule in a particular disintegrated ion cluster carries only a small fraction of the total cluster energy. Consequently, the impact effects of large ion clusters are substantial, but are limited to a very shallow surface region. This makes gas cluster ions effective for a variety of surface modification processes, but without the tendency to produce deeper sub-surface damage that is characteristic of conventional ion beam processing.

Conventional cluster ion sources produce cluster ions having a wide size distribution scaling with the number of molecules in each cluster that may reach several thousand molecules. Clusters of atoms can be formed by the condensation of individual gas atoms (or molecules) during the adiabatic expansion of high pressure gas from a nozzle into a vacuum. A skimmer with a small aperture strips divergent streams from the core of this expanding gas flow to produce a collimated beam of clusters. Neutral clusters of various sizes are produced and held together by weak inter-atomic forces known as Van der Waals forces. This method has been used to produce beams of clusters from a variety of gases, such as helium, neon, argon, krypton, xenon, nitrogen, oxygen, carbon dioxide, sulfur hexafluoride, nitric oxide, and nitrous oxide, and mixtures of these gases.

Several emerging applications for GCIB processing of substrates on an industrial scale are in the semiconductor field. One such application includes thin film formation. However, some films pose more formidable challenges when using GCIB processing due to the incompatibility of gases. Furthermore, many GCIB processes fail to provide adequate control of critical properties and/or dimensions of the surface, structure, and/or film.

### SUMMARY OF THE INVENTION

The invention relates to a method for forming a thin film using gas cluster ion beam (GCIB) processing.

The invention relates to a method for performing multi-sequence deposition and growth for thin film formation on a substrate using GCIB processing. The invention further relates to a method for performing multi-sequence deposition and oxidation for thin film formation on a substrate using GCIB processing.

According to one embodiment, a method of forming a thin film on a substrate is described. The method comprises depositing a first material layer on a substrate to a first thickness using a first GCIB, the first material layer comprising a first atomic constituent, and growing a second material layer from at least a surface portion of the first material layer by introducing a second atomic constituent using a second GCIB, the second material layer comprising a reaction product of the first and second atomic constituents.

According to another embodiment, a method of forming a thin silicon-containing oxide film on a substrate is described. The method comprises depositing a layer of silicon-containing material on a substrate using a first GCIB, and oxidizing the layer of silicon-containing material on the substrate by introducing oxygen using a second GCIB.

According to yet another embodiment, a processing platform for forming a thin film on a substrate is described. The processing platform comprises a first GCIB processing system configured to generate a first GCIB containing a first atomic constituent from a first gas source and to deposit a first material layer on a substrate using the first GCIB; a second GCIB processing system configured to generate a second GCIB containing a second atomic constituent from a second gas source and to grow a second material layer from at least a surface portion of the first material layer using the second GCIB; and a substrate handling system coupled to the first GCIB processing system and the second GCIB processing system, and configured to transport one or more substrates to and from the first GCIB processing system and the second GCIB processing system.

### BRIEF DESCRIPTION OF THE DRAWINGS

In the accompanying drawings:

FIGS. 1A through 1E illustrate, in schematic cross-sectional view, a method for forming a thin film;

FIG. 2 is an illustration of a GCIB processing system;

FIG. 3 is another illustration of a GCIB processing system;

FIG. 4 is yet another illustration of a GCIB processing system;

FIG. 5 is an illustration of an ionization source for a GCIB processing system;

FIG. 6 is a schematic illustration of a cluster tool platform with multiple GCIB processing systems according to an embodiment;

FIG. 7 is a flow chart illustrating a method for forming a thin film on a substrate according to an embodiment; and

FIGS. 8-10 are graphs that provide exemplary data for thin film formation using a GCIB.

### DETAILED DESCRIPTION OF SEVERAL EMBODIMENTS

A method and system for forming a thin film on a substrate using a gas cluster ion beam (GCIB) is disclosed in various embodiments. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

In the description and claims, the terms “coupled” and “connected,” along with their derivatives, are used. It should be understood that these terms are not intended as synonyms for each other. Rather, in particular embodiments, “connected” may be used to indicate that two or more elements are in direct physical or electrical contact with each other while “coupled” may further mean that two or more elements are not in direct contact with each other, but yet still co-operate or interact with each other.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

“Substrate” as used herein generically refers to the object being processed in accordance with the invention. The substrate may include any material portion or structure of a device, particularly a semiconductor or other electronic device, and may, for example, be a base substrate structure, such as a semiconductor wafer or a layer on or overlying a base substrate structure such as a thin film. Thus, substrate is not intended to be limited to any particular base structure, underlying layer or overlying layer, patterned or unpatterned, but rather, is contemplated to include any such layer or base structure, and any combination of layers and/or base structures. The description below may reference particular types of substrates, but this is for illustrative purposes only and not limitation.

As described above, there is a general need for forming thin films of material on a surface of a substrate using a GCIB. In particular, there is a need to form thin films on a substrate while, among other things, mitigating source gas incompatibilities and providing adequate control of critical properties and/or dimensions of the surface, structure, and/or film subject to GCIB treatment.

Herein, the term “to form” (or “forming”, or “formation”) is used to broadly represent the preparation of a thin film of material on one or more surfaces of a substrate. Additionally herein, “growth” and “deposition” are defined and used in a manner to distinguish from one another. During growth, a thin film is formed on a substrate, wherein only a fraction of the atomic constituents of the thin film are introduced in the GCIB and the remaining fraction is provided by the substrate upon which the thin film is grown. For example, when growing SiOₓ on a substrate, the substrate may comprise a silicon surface, which is irradiated by a GCIB containing oxygen. The grown layer is thus a reaction product of the silicon from the silicon surface and the oxygen from the GCIB. To the contrary, during deposition, a thin film is formed on a substrate, wherein substantially all of the atomic constituents of the thin film are introduced in the GCIB. For example, when depositing SiCₓ, the substrate is irradiated by a GCIB containing both silicon and carbon.

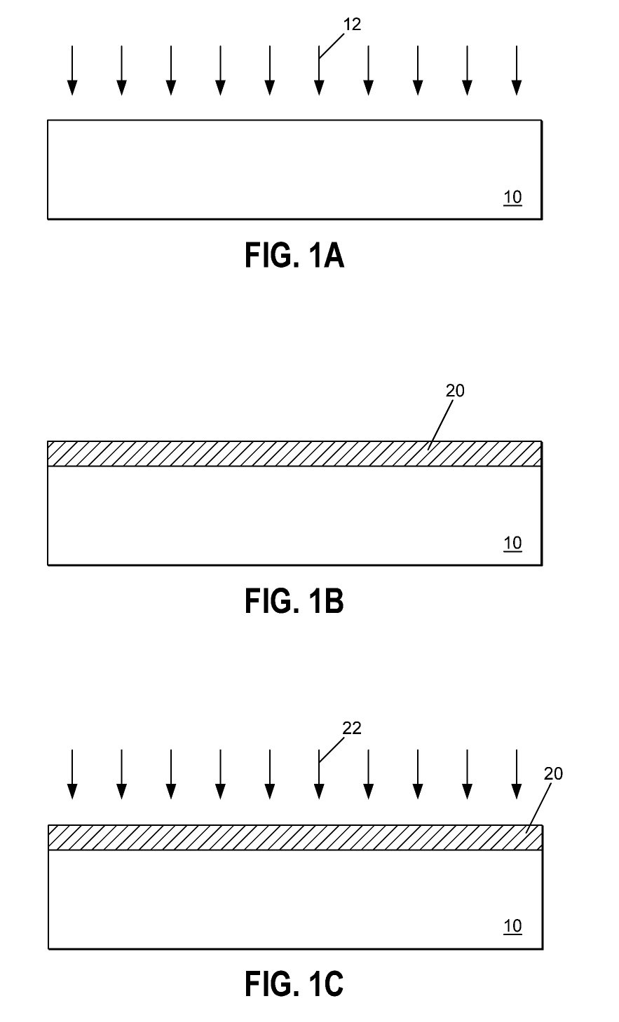

Herein, according to one embodiment, a method of forming a thin film on a substrate is described. The method comprises depositing a first material layer on a substrate using a first GCIB, and growing a second material layer from at least a surface portion of the first material layer using a second GCIB. As shown in FIGS. 1A and 1B, a first material layer 20 is formed on a substrate 10 by exposing the substrate 10 to a GCIB 12. GCIB 12 includes a first atomic constituent, and may include additional atomic constituents. The deposited first material layer 20 likewise includes the first atomic constituent, and if present, the additional atomic constituents.

Thereafter, as shown in FIGS. 1C and 1D, a second material layer 30 is grown from at least a surface portion of the first material layer 20 by introducing a second atomic constituent using a second GCIB 22. GCIB 22 includes at least the second atomic constituent, and may include additional atomic constituents, that form a reaction product with the first atomic constituent to form the second material layer 30. As illustrated in FIG. 1D, the growth of the second material layer 30 penetrates the entire depth of the first material layer 20, whereby the first material layer 20 is fully reacted, and thus essentially consumed, during growth of the second material layer 30. However, the growth of the second material layer 30 may only penetrate and react with a portion of the first material layer 20, as illustrated in FIG. 1E.

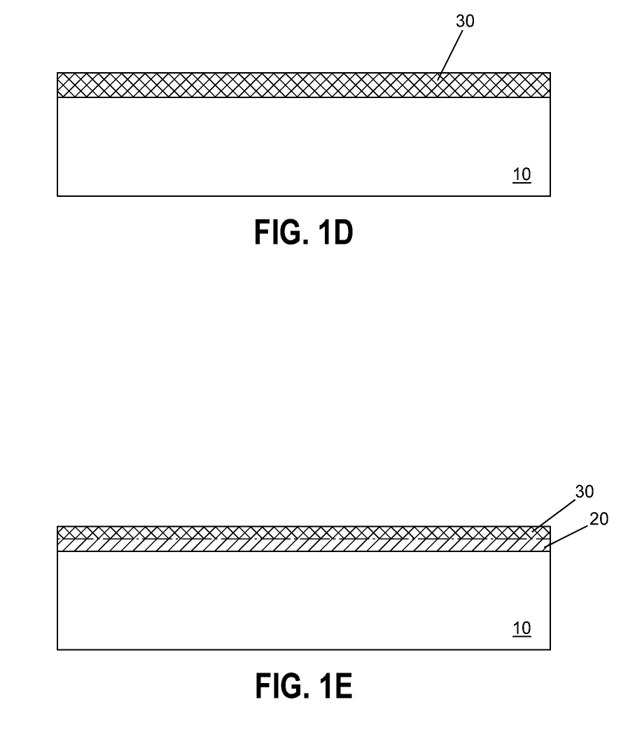

Referring now to FIG. 2, a GCIB processing system 100 for depositing and growing a thin film as described above is depicted according to an embodiment. The GCIB processing system 100 comprises a vacuum vessel 102, substrate holder 150, upon which a substrate 152 to be processed is affixed, and vacuum pumping systems 170A, 170B, and 170C. Substrate 152 can be a semiconductor substrate, a wafer, a flat panel display (FPD), a liquid crystal display (LCD), or any other workpiece. GCIB processing system 100 is configured to produce a GCIB for treating substrate 152.

Referring still to GCIB processing system 100 in FIG. 2, the vacuum vessel 102 comprises three communicating chambers, namely, a source chamber 104, an ionization/acceleration chamber 106, and a processing chamber 108 to provide a reduced-pressure enclosure. The three chambers are evacuated to suitable operating pressures by vacuum pumping systems 170A, 170B, and 170C, respectively. In the three communicating chambers 104, 106, 108, a gas cluster beam can be formed in the first chamber (source chamber 104), while a GCIB can be formed in the second chamber (ionization/acceleration chamber 106) wherein the gas cluster beam is ionized and accelerated. Then, in the third chamber (processing chamber 108), the accelerated GCIB may be utilized to treat substrate 152.

As shown in FIG. 2, GCIB processing system 100 can comprise at least two gas sources configured to introduce at least two gases or mixture of gases to vacuum vessel 102. For example, a first gas composition stored in a first gas source 111 is admitted under pressure through a first gas control valve 113A to a gas metering valve or valves 113. Additionally, for example, a second gas composition stored in a second gas source 112 is admitted under pressure through a second gas control valve 113B to the gas metering valve or valves 113. Further, for example, the first gas composition or second gas composition or both can include a condensable inert gas, carrier gas or dilution gas. For example, the inert gas, carrier gas or dilution gas can include a noble gas, i.e., He, Ne, Ar, Kr, Xe, or Rn.

Furthermore, the first gas source 111 and the second gas source 112 are each utilized to produce ionized clusters. The material compositions of the first and second gas sources 111, 112 include the principal atomic (or molecular) species, i.e., the first and second atomic constituents desired to be introduced for depositing and growing the thin film.

The high pressure, condensable gas comprising the first gas composition or the second gas composition is introduced through gas feed tube 114 into stagnation chamber 116 and is ejected into the substantially lower pressure vacuum through a properly shaped nozzle 110. As a result of the expansion of the high pressure, condensable gas from the stagnation chamber 116 to the lower pressure region of the source chamber 104, the gas velocity accelerates to supersonic speeds and gas cluster beam 118 emanates from nozzle 110.

The inherent cooling of the jet as static enthalpy is exchanged for kinetic energy, which results from the expansion in the jet, causes a portion of the gas jet to condense and form a gas cluster beam 118 having clusters, each consisting of from several to several thousand weakly bound atoms or molecules. A gas skimmer 120, positioned downstream from the exit of the nozzle 110 between the source chamber 104 and ionization/acceleration chamber 106, partially separates the gas molecules on the peripheral edge of the gas cluster beam 118, that may not have condensed into a cluster, from the gas molecules in the core of the gas cluster beam 118, that may have formed clusters. Among other reasons, this selection of a portion of gas cluster beam 118 can lead to a reduction in the pressure in the downstream regions where higher pressures may be detrimental (e.g., ionizer 122, and processing chamber 108). Furthermore, gas skimmer 120 defines an initial dimension for the gas cluster beam entering the ionization/acceleration chamber 106.

After the gas cluster beam 118 has been formed in the source chamber 104, the constituent gas clusters in gas cluster beam 118 are ionized by ionizer 122 to form GCIB 128. The ionizer 122 may include an electron impact ionizer that produces electrons from one or more filaments 124, which are accelerated and directed to collide with the gas clusters in the gas cluster beam 118 inside the ionization/acceleration chamber 106. Upon collisional impact with the gas cluster, electrons of sufficient energy eject electrons from molecules in the gas clusters to generate ionized molecules. The ionization of gas clusters can lead to a population of charged gas cluster ions, generally having a net positive charge.

As shown in FIG. 2, beam electronics 130 are utilized to ionize, extract, accelerate, and focus the GCIB 128. The beam electronics 130 include a filament power supply 136 that provides voltage V_{F} to heat the ionizer filament 124.

Additionally, the beam electronics 130 include a set of suitably biased high voltage electrodes 126 in the ionization/acceleration chamber 106 that extracts the cluster ions from the ionizer 122. The high voltage electrodes 126 then accelerate the extracted cluster ions to a desired energy and focus them to define GCIB 128. The kinetic energy of the cluster ions in GCIB 128 typically ranges from about 1000 electron volts (1 keV) to several tens of keV. For example, GCIB 128 can be accelerated to 1 to 100 keV.

As illustrated in FIG. 2, the beam electronics 130 further include an anode power supply 134 that provides voltage V_{A} to an anode of ionizer 122 for accelerating electrons emitted from filament 124 and causing the electrons to bombard the gas clusters in gas cluster beam 118, which produces cluster ions.

Additionally, as illustrated in FIG. 2, the beam electronics 130 include an extraction power supply 138 that provides voltage V_{E} to bias at least one of the high voltage electrodes 126 to extract ions from the ionizing region of ionizer 122 and to form the GCIB 128. For example, extraction power supply 138 provides a voltage to a first electrode of the high voltage electrodes 126 that is less than or equal to the anode voltage of ionizer 122.

Furthermore, the beam electronics 130 can include an accelerator power supply 140 that provides voltage V_{Acc} to bias one of the high voltage electrodes 126 with respect to the ionizer 122 so as to result in a total GCIB acceleration energy equal to about V_{Acc} electron volts (eV). For example, accelerator power supply 140 provides a voltage to a second electrode of the high voltage electrodes 126 that is less than or equal to the anode voltage of ionizer 122 and the extraction voltage of the first electrode.

Further yet, the beam electronics 130 can include lens power supplies 142, 144 that may be provided to bias some of the high voltage electrodes 126 with potentials (e.g., V_{L1} and V_{L2}) to focus the GCIB 128. For example, lens power supply 142 can provide a voltage to a third electrode of the high voltage electrodes 126 that is less than or equal to the anode voltage of ionizer 122, the extraction voltage of the first electrode, and the accelerator voltage of the second electrode, and lens power supply 144 can provide a voltage to a fourth electrode of the high voltage electrodes 126 that is less than or equal to the anode voltage of ionizer 122, the extraction voltage of the first electrode, the accelerator voltage of the second electrode, and the first lens voltage of the third electrode.

Note that many variants on both the ionization and extraction schemes may be used. While the scheme described here is useful for purposes of instruction, another extraction scheme involves placing the ionizer and the first element of the extraction electrode(s) (or extraction optics) at V_{Acc}. This typically requires fiber optic programming of control voltages for the ionizer power supply, but creates a simpler overall optics train. The invention described herein is useful regardless of the details of the ionizer and extraction lens biasing.

A beam filter 146 in the ionization/acceleration chamber 106 downstream of the high voltage electrodes 126 can be utilized to eliminate monomers, or monomers and light cluster ions from the GCIB 128 to define a filtered process GCIB 128A that enters the processing chamber 108. In one embodiment, the beam filter 146 substantially reduces the number of clusters having 100 or less atoms or molecules or both. The beam filter may comprise a magnet assembly for imposing a magnetic field across the GCIB 128 to aid in the filtering process.

Referring still to FIG. 2, a beam gate 148 is disposed in the path of GCIB 128 in the ionization/acceleration chamber 106. Beam gate 148 has an open state in which the GCIB 128 is permitted to pass from the ionization/acceleration chamber 106 to the processing chamber 108 to define process GCIB 128A, and a closed state in which the GCIB 128 is blocked from entering the processing chamber 108. A control cable conducts control signals from control system 190 to beam gate 148. The control signals controllably switch beam gate 148 between the open or closed states.

A substrate 152, which may be a wafer or semiconductor wafer, a flat panel display (FPD), a liquid crystal display (LCD), or other substrate to be processed by GCIB processing, is disposed in the path of the process GCIB 128A in the processing chamber 108. Because most applications contemplate the processing of large substrates with spatially uniform results, a scanning system may be desirable to uniformly scan the process GCIB 128A across large areas to produce spatially homogeneous results.

An X-scan actuator 160 provides linear motion of the substrate holder 150 in the direction of X-scan motion (into and out of the plane of the paper). A Y-scan actuator 162 provides linear motion of the substrate holder 150 in the direction of Y-scan motion 164, which is typically orthogonal to the X-scan motion. The combination of X-scanning and Y-scanning motions translates the substrate 152, held by the substrate holder 150, in a raster-like scanning motion through process GCIB 128A to cause a uniform (or otherwise programmed) irradiation of a surface of the substrate 152 by the process GCIB 128A for processing of the substrate 152.

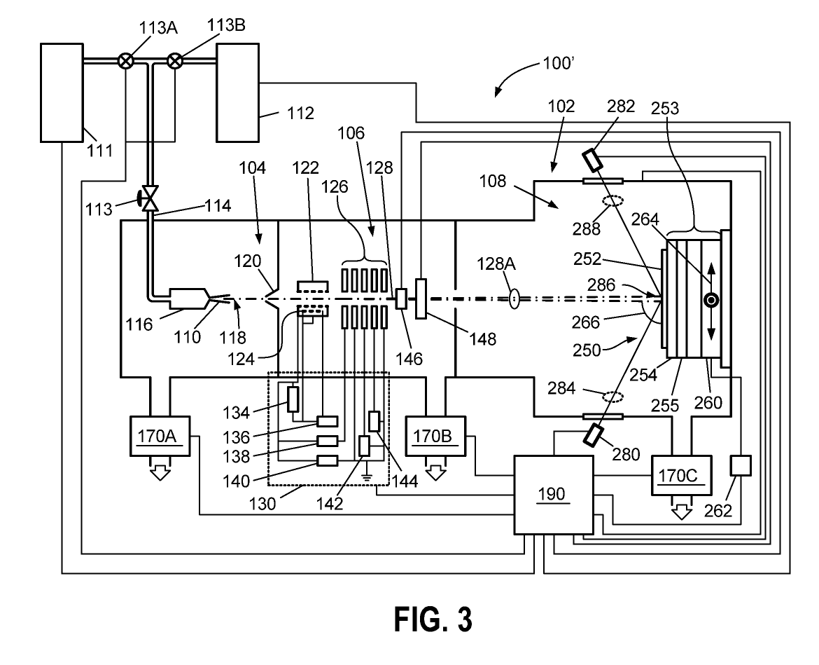

The substrate holder 150 disposes the substrate 152 at an angle with respect to the axis of the process GCIB 128A so that the process GCIB 128A has an angle of beam incidence 166 with respect to a substrate 152 surface. The angle of beam incidence 166 may be 90 degrees or some other angle, but is typically 90 degrees or near 90 degrees. During Y-scanning, the substrate 152 and the substrate holder 150 move from the shown position to the alternate position “A” indicated by the designators 152A and 150A, respectively. Notice that in moving between the two positions, the substrate 152 is scanned through the process GCIB 128A, and in both extreme positions, is moved completely out of the path of the process GCIB 128A (over-scanned). Though not shown explicitly in FIG. 4, similar scanning and over-scan is performed in the (typically) orthogonal X-scan motion direction (in and out of the plane of the paper).

A beam current sensor 180 may be disposed beyond the substrate holder 150 in the path of the process GCIB 128A so as to intercept a sample of the process GCIB 128A when the substrate holder 150 is scanned out of the path of the process GCIB 128A. The beam current sensor 180 is typically a faraday cup or the like, closed except for a beam-entry opening, and is typically affixed to the wall of the vacuum vessel 102 with an electrically insulating mount 182.

As shown in FIG. 2, control system 190 connects to the X-scan actuator 160 and the Y-scan actuator 162 through electrical cable and controls the X-scan actuator 160 and the Y-scan actuator 162 in order to place the substrate 152 into or out of the process GCIB 128A and to scan the substrate 152 uniformly relative to the process GCIB 128A to achieve desired processing of the substrate 152 by the process GCIB 128A. Control system 190 receives the sampled beam current collected by the beam current sensor 180 by way of an electrical cable and, thereby, monitors the GCIB and controls the GCIB dose received by the substrate 152 by removing the substrate 152 from the process GCIB 128A when a predetermined dose has been delivered.

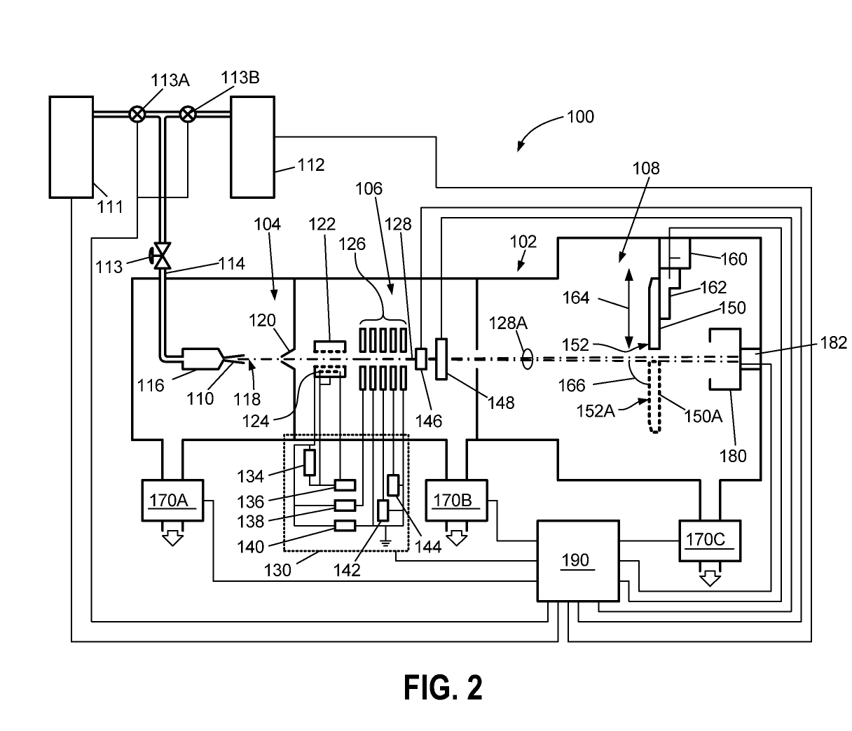

In the embodiment shown in FIG. 3, the GCIB processing system 100′ can be similar to the embodiment of FIG. 2 and further comprise a X-Y positioning table 253 operable to hold and move a substrate 252 in two axes, effectively scanning the substrate 252 relative to the process GCIB 128A. For example, the X-motion can include motion into and out of the plane of the paper, and the Y-motion can include motion along direction 264.

The process GCIB 128A impacts the substrate 252 at a projected impact region 286 on a surface of the substrate 252, and at an angle of beam incidence 266 with respect to the surface of substrate 252. By X-Y motion, the X-Y positioning table 253 can position each portion of a surface of the substrate 252 in the path of process GCIB 128A so that every region of the surface may be made to coincide with the projected impact region 286 for processing by the process GCIB 128A. An X-Y controller 262 provides electrical signals to the X-Y positioning table 253 through an electrical cable for controlling the position and velocity in each of X-axis and Y-axis directions. The X-Y controller 262 receives control signals from, and is operable by, control system 190 through an electrical cable. X-Y positioning table 253 moves by continuous motion or by stepwise motion according to conventional X-Y table positioning technology to position different regions of the substrate 252 within the projected impact region 286. In one embodiment, X-Y positioning table 253 is programmably operable by the control system 190 to scan, with programmable velocity, any portion of the substrate 252 through the projected impact region 286 for GCIB processing by the process GCIB 128A.

The substrate holding surface 254 of positioning table 253 is electrically conductive and is connected to a dosimetry processor operated by control system 190. An electrically insulating layer 255 of positioning table 253 isolates the substrate 252 and substrate holding surface 254 from the base portion 260 of the positioning table 253. Electrical charge induced in the substrate 252 by the impinging process GCIB 128A is conducted through substrate 252 and substrate holding surface 254, and a signal is coupled through the positioning table 253 to control system 190 for dosimetry measurement. Dosimetry measurement has integrating means for integrating the GCIB current to determine a GCIB processing dose. Under certain circumstances, a target-neutralizing source (not shown) of electrons, sometimes referred to as electron flood, may be used to neutralize the process GCIB 128A. In such case, a Faraday cup (not shown, but which may be similar to beam current sensor 180 in FIG. 2) may be used to assure accurate dosimetry despite the added source of electrical charge, the reason being that typical Faraday cups allow only the high energy positive ions to enter and be measured.

In operation, the control system 190 signals the opening of the beam gate 148 to irradiate the substrate 252 with the process GCIB 128A. The control system 190 monitors measurements of the GCIB current collected by the substrate 252 in order to compute the accumulated dose received by the substrate 252. When the dose received by the substrate 252 reaches a predetermined dose, the control system 190 closes the beam gate 148 and processing of the substrate 252 is complete. Based upon measurements of the GCIB dose received for a given area of the substrate 252, the control system 190 can adjust the scan velocity in order to achieve an appropriate beam dwell time to treat different regions of the substrate 252.

Alternatively, the process GCIB 128A may be scanned at a constant velocity in a fixed pattern across the surface of the substrate 252; however, the GCIB intensity is modulated (may be referred to as Z-axis modulation) to deliver an intentionally non-uniform dose to the sample. The GCIB intensity may be modulated in the GCIB processing system 100′ by any of a variety of methods, including varying the gas flow from a GCIB source supply; modulating the ionizer 122 by either varying a filament voltage V_{F} or varying an anode voltage V_{A}; modulating the lens focus by varying lens voltages V_{L1} and/or V_{L2}; or mechanically blocking a portion of the GCIB with a variable beam block, adjustable shutter, or variable aperture. The modulating variations may be continuous analog variations or may be time modulated switching or gating.

The processing chamber 108 may further include an in-situ metrology system. For example, the in-situ metrology system may include an optical diagnostic system having an optical transmitter 280 and optical receiver 282 configured to illuminate substrate 252 with an incident optical signal 284 and to receive a scattered optical signal 288 from substrate 252, respectively. The optical diagnostic system comprises optical windows to permit the passage of the incident optical signal 284 and the scattered optical signal 288 into and out of the processing chamber 108. Furthermore, the optical transmitter 280 and the optical receiver 282 may comprise transmitting and receiving optics, respectively. The optical transmitter 280 receives, and is responsive to, controlling electrical signals from the control system 190. The optical receiver 282 returns measurement signals to the control system 190.

The in-situ metrology system may comprise any instrument configured to monitor the progress of the GCIB processing. According to one embodiment, the in-situ metrology system may constitute an optical scatterometry system. The scatterometry system may include a scatterometer, incorporating beam profile ellipsometry (ellipsometer) and beam profile reflectometry (reflectometer), commercially available from Therma-Wave, Inc. (1250 Reliance Way, Fremont, Calif. 94539) or Nanometrics, Inc. (1550 Buckeye Drive, Milpitas, Calif. 95035).

For instance, the in-situ metrology system may include an integrated Optical Digital Profilometry (iODP) scatterometry module configured to measure process performance data resulting from the execution of a treatment process in the GCIB processing system 100′. The metrology system may, for example, measure or monitor metrology data resulting from the treatment process. The metrology data can, for example, be utilized to determine process performance data that characterizes the treatment process, such as a process rate, a relative process rate, a feature profile angle, a critical dimension, a feature thickness or depth, a feature shape, etc. For example, in a process for directionally depositing material on a substrate, process performance data can include a critical dimension (CD), such as a top, middle or bottom CD in a feature (i.e., via, line, etc.), a feature depth, a material thickness, a sidewall angle, a sidewall shape, a deposition rate, a relative deposition rate, a spatial distribution of any parameter thereof, a parameter to characterize the uniformity of any spatial distribution thereof, etc. Operating the X-Y positioning table 253 via control signals from control system 190, the in-situ metrology system can map one or more characteristics of the substrate 252.

In the embodiment shown in FIG. 4, the GCIB processing system 100″ can be similar to the embodiment of FIG. 2 and further comprise a pressure cell chamber 350 positioned, for example, at or near an outlet region of the ionization/acceleration chamber 106. The pressure cell chamber 350 comprises an inert gas source 352 configured to supply a background gas to the pressure cell chamber 350 for elevating the pressure in the pressure cell chamber 350, and a pressure sensor 354 configured to measure the elevated pressure in the pressure cell chamber 350.

The pressure cell chamber 350 may be configured to modify the beam energy distribution of GCIB 128 to produce a modified processing GCIB 128A′. This modification of the beam energy distribution is achieved by directing GCIB 128 along a GCIB path through an increased pressure region within the pressure cell chamber 350 such that at least a portion of the GCIB traverses the increased pressure region. The extent of modification to the beam energy distribution may be characterized by a pressure-distance integral along at least a portion of the GCIB path, where distance (or length of the pressure cell chamber 350) is indicated by path length (d). When the value of the pressure-distance integral is increased (either by increasing the pressure and/or the path length (d)), the beam energy distribution is broadened and the peak energy is decreased. When the value of the pressure-distance integral is decreased (either by decreasing the pressure and/or the path length (d)), the beam energy distribution is narrowed and the peak energy is increased. Further details for the design of a pressure cell may be determined from U.S. Pat. No. 7,060,989, entitled METHOD AND APPARATUS FOR IMPROVED PROCESSING WITH A GAS-CLUSTER ION BEAM; the content of which is incorporated herein by reference in its entirety.

Control system 190 comprises a microprocessor, memory, and a digital I/O port capable of generating control voltages sufficient to communicate and activate inputs to GCIB processing system 100 (or 100′, 100″), as well as monitor outputs from GCIB processing system 100 (or 100′, 100″). Moreover, control system 190 can be coupled to and can exchange information with vacuum pumping systems 170A, 170B, and 170C, first gas source 111, second gas source 112, first gas control valve 113A, second gas control valve 113B, beam electronics 130, beam filter 146, beam gate 148, the X-scan actuator 160, the Y-scan actuator 162, and beam current sensor 180. For example, a program stored in the memory can be utilized to activate the inputs to the aforementioned components of GCIB processing system 100 according to a process recipe in order to perform a GCIB process on substrate 152.

However, the control system 190 may be implemented as a general purpose computer system that performs a portion or all of the microprocessor based processing steps of the invention in response to a processor executing one or more sequences of one or more instructions contained in a memory. Such instructions may be read into the controller memory from another computer readable medium, such as a hard disk or a removable media drive. One or more processors in a multi-processing arrangement may also be employed as the controller microprocessor to execute the sequences of instructions contained in main memory. In alternative embodiments, hard-wired circuitry may be used in place of or in combination with software instructions. Thus, embodiments are not limited to any specific combination of hardware circuitry and software.

The control system 190 can be used to configure any number of processing elements, as described above, and the control system 190 can collect, provide, process, store, and display data from processing elements. The control system 190 can include a number of applications, as well as a number of controllers, for controlling one or more of the processing elements. For example, control system 190 can include a graphic user interface (GUI) component (not shown) that can provide interfaces that enable a user to monitor and/or control one or more processing elements.

Control system 190 can be locally located relative to the GCIB processing system 100 (or 100′, 100″), or it can be remotely located relative to the GCIB processing system 100 (or 100′, 100″). For example, control system 190 can exchange data with GCIB processing system 100 using a direct connection, an intranet, and/or the internet. Control system 190 can be coupled to an intranet at, for example, a customer site (i.e., a device maker, etc.), or it can be coupled to an intranet at, for example, a vendor site (i.e., an equipment manufacturer). Alternatively or additionally, control system 190 can be coupled to the internet. Furthermore, another computer (i.e., controller, server, etc.) can access control system 190 to exchange data via a direct connection, an intranet, and/or the internet.

Substrate 152 (or 252) can be affixed to the substrate holder 150 (or substrate holder 250) via a clamping system (not shown), such as a mechanical clamping system or an electrical clamping system (e.g., an electrostatic clamping system). Furthermore, substrate holder 150 (or 250) can include a heating system (not shown) or a cooling system (not shown) that is configured to adjust and/or control the temperature of substrate holder 150 (or 250) and substrate 152 (or 252).

Vacuum pumping systems 170A, 170B, and 170C can include turbo-molecular vacuum pumps (TMP) capable of pumping speeds up to about 5000 liters per second (and greater) and a gate valve for throttling the chamber pressure. In conventional vacuum processing devices, a 1000 to 3000 liter per second TMP can be employed. TMPs are useful for low pressure processing, typically less than about 50 mTorr. Although not shown, it may be understood that pressure cell chamber 350 may also include a vacuum pumping system. Furthermore, a device for monitoring chamber pressure (not shown) can be coupled to the vacuum vessel 102 or any of the three vacuum chambers 104, 106, 108. The pressure-measuring device can be, for example, a capacitance manometer or ionization gauge.

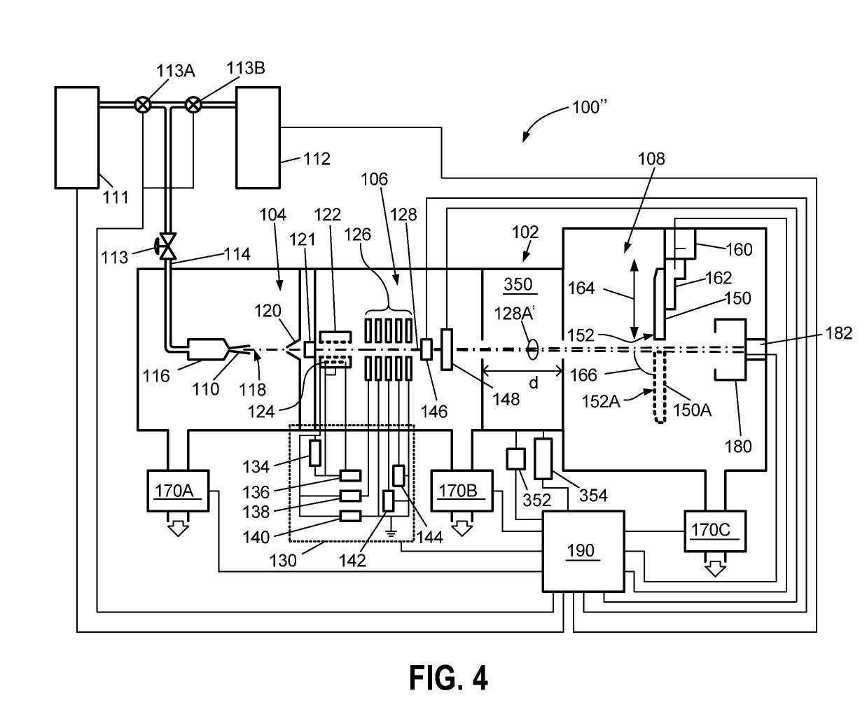

Referring now to FIG. 5, a section 300 of a gas cluster ionizer (122, FIGS. 2, 3 and 4) for ionizing a gas cluster jet (gas cluster beam 118, FIGS. 2, 3 and 4) is shown. The section 300 is normal to the axis of GCIB 128. For typical gas cluster sizes (2000 to 15000 atoms), clusters leaving the skimmer aperture (120, FIGS. 2, 3 and 4) and entering an ionizer (122, FIGS. 2, 3 and 4) will travel with a kinetic energy of about 130 to 1000 electron volts (eV). At these low energies, any departure from space charge neutrality within the ionizer 122 will result in a rapid dispersion of the jet with a significant loss of beam current. FIG. 5 illustrates a self-neutralizing ionizer. As with other ionizers, gas clusters are ionized by electron impact. In this design, thermo-electrons (seven examples indicated by 310) are emitted from multiple linear thermionic filaments 302a, 302b, and 302c (typically tungsten) and are extracted and focused by the action of suitable electric fields provided by electron-repeller electrodes 306a, 306b, and 306c and beam-forming electrodes 304a, 304b, and 304c. Thermo-electrons 310 pass through the gas cluster jet and the jet axis and then strike the opposite beam-forming electrode 304b to produce low energy secondary electrons (312, 314, and 316 indicated for examples).

Though (for simplicity) not shown, linear thermionic filaments 302b and 302c also produce thermo-electrons that subsequently produce low energy secondary electrons. All the secondary electrons help ensure that the ionized cluster jet remains space charge neutral by providing low energy electrons that can be attracted into the positively ionized gas cluster jet as required to maintain space charge neutrality. Beam-forming electrodes 304a, 304b, and 304c are biased positively with respect to linear thermionic filaments 302a, 302b, and 302c and electron-repeller electrodes 306a, 306b, and 306c are negatively biased with respect to linear thermionic filaments 302a, 302b, and 302c. Insulators 308a, 308b, 308c, 308d, 308e, and 308f electrically insulate and support electrodes 304a, 304b, 304c, 306a, 306b, and 306c. For example, this self-neutralizing ionizer is effective and achieves over 1000 micro Amps argon GCIBs.

Alternatively, ionizers may use electron extraction from plasma to ionize clusters. The geometry of these ionizers is quite different from the three filament ionizer described here but the principles of operation and the ionizer control are very similar. For example, the ionizer design may be similar to the ionizer described in U.S. Pat. No. 7,173,252, entitled IONIZER AND METHOD FOR GAS-CLUSTER ION-BEAM FORMATION; the content of which is incorporated herein by reference in its entirety.

The gas cluster ionizer (122, FIGS. 2, 3 and 4) may be configured to modify the beam energy distribution of GCIB 128 by altering the charge state of the GCIB 128. For example, the charge state may be modified by adjusting an electron flux, an electron energy, or an electron energy distribution for electrons utilized in electron collision-induced ionization of gas clusters.

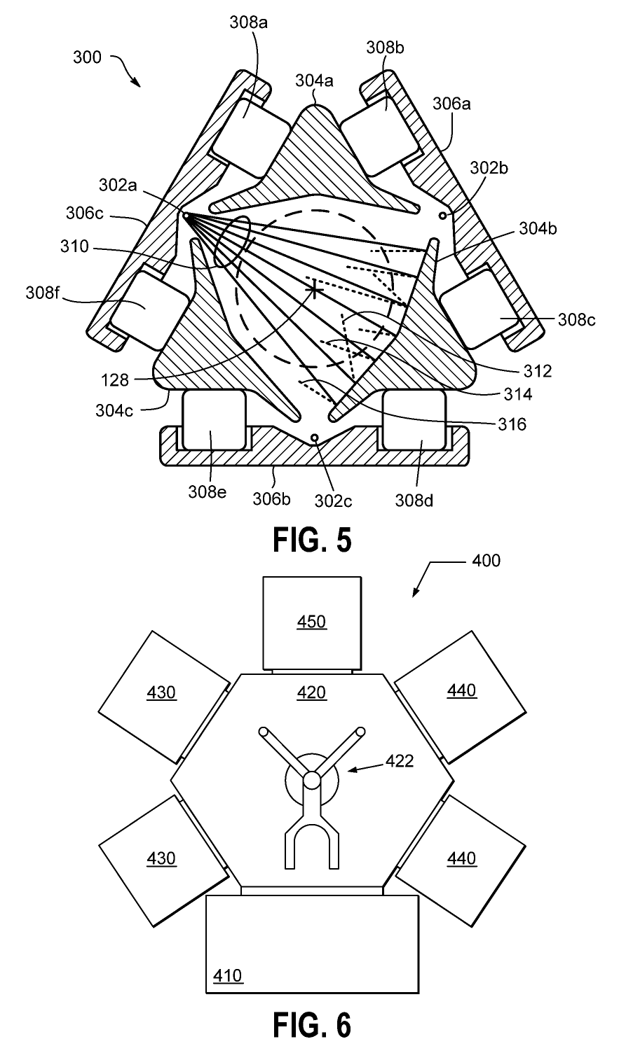

Referring now to FIG. 6, a processing platform 400 is illustrated for forming a thin film on a substrate according to one embodiment. The processing platform 400 includes at least one first GCIB processing system 430 (two shown), and at least one second GCIB processing system 440 (two shown). For example, the first GCIB processing system 430 can be configured to deposit a first material layer on the substrate, and the second GCIB processing system 440 may be configured to grow a second material layer from the first material layer. Thus, first GCIB processing system 430 is coupled to a first gas source and configured to generate a first GCIB containing the first atomic constituent to deposit the first material layer containing the first atomic constituent onto a substrate. The second GCIB processing system 440 is coupled to a second gas source and configured to generate a second GCIB containing the second atomic constituent to react with the first atomic constituent of the first material layer to grow the second material layer.

Additionally, processing system 400 includes a substrate handling system 420 coupled to the first GCIB processing system 430, the second GCIB processing system 440, and an auxiliary processing system 450, and configured to transfer one or more substrates in and out of the first GCIB processing system 430, the second GCIB processing system 440, and the auxiliary processing system 450, and also to exchange one or more substrates with a transfer system 410. The transfer system 410 may comprise a load-lock element to allow cassettes of substrates to cycle between ambient conditions and low pressure conditions.

The first and second GCIB processing systems 430, 440, the auxiliary processing system 450, and the substrate handling system 420 can, for example, comprise a processing element within the multi-element manufacturing system which is interfaced by transfer system 410. The substrate handling system 420 may comprise a dedicated substrate handler 422 for moving one or more substrates between the first GCIB processing system 430, the second GCIB processing system 440, the auxiliary processing system 450, and the transfer system 410.

In one embodiment, the transfer system 410 may permit the transfer of substrates to and from processing elements including such devices as etch systems, deposition systems, coating systems, patterning systems, metrology systems, etc. Furthermore, the transfer system 410 may permit the transfer of substrates to and from an auxiliary process system 450, wherein the auxiliary processing system 450 may include an etch system, a deposition system, a coating system, a patterning system, a metrology system, an annealing system, a pre-treatment system, a post-treatment system, etc. As an example, the auxiliary processing system 450 may include a pre-treatment system or post-treatment system for pre-treating the substrate prior to film formation or post-treating the film, respectively.

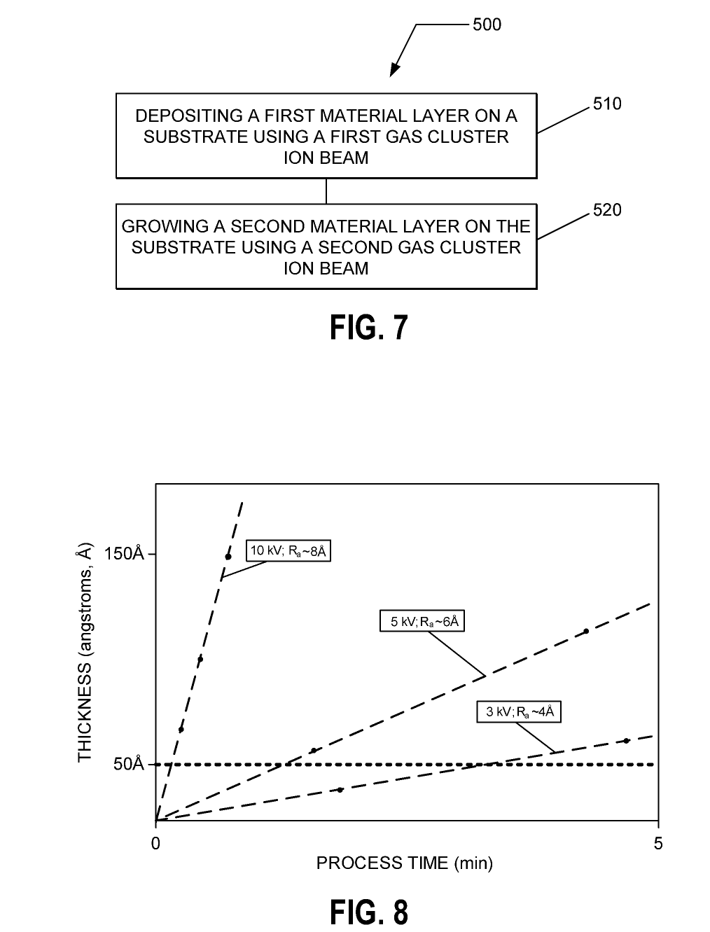

Referring now to FIG. 7, a method of forming a thin film on a substrate using a GCIB is illustrated according to an embodiment. The method comprises a flow chart 500 beginning in 510 with depositing a first material layer on a substrate using a first GCIB. As an example, the first GCIB may comprise silicon as the first atomic constituent, such that the deposited first material layer may be a silicon or silicon-containing layer.

The substrate may be disposed in a first GCIB processing system (e.g., first GCIB processing system 430). The first GCIB processing system can be any of the GCIB processing systems (100, 100′ or 100″) described above in FIGS. 2, 3 or 4, or any combination thereof. The substrate can include a conductive material, a non-conductive material, or a semi-conductive material, or a combination of two or more materials thereof. Additionally, the substrate may include one or more material structures formed thereon, or the substrate may be a blanket substrate free of material structures.

The substrate can be positioned in the first GCIB processing system on a substrate holder and may be securely held by the substrate holder. The temperature of the substrate may or may not be controlled. For example, the substrate may be heated or cooled during a film forming process. The environment surrounding the substrate is maintained at a reduced pressure. A first GCIB is generated in the reduced-pressure environment. The first GCIB can be generated from a pressurized gas mixture having a film forming composition comprising a first atomic constituent (or constituents) and an optional inert gas. A beam acceleration potential and a beam dose can be selected. The beam acceleration potential and the beam dose can be selected to achieve a desired thickness of the deposited thin film, and to achieve a desired surface roughness of an upper surface of the deposited thin film.

Herein, beam dose is given the units of number of clusters per unit area. However, beam dose may also include beam current and/or time (e.g., GCIB dwell time). For example, the beam current may be measured and maintained constant, while time is varied to change the beam dose. Alternatively, for example, the rate at which clusters strike the surface of the substrate per unit area (i.e., number of clusters per unit area per unit time) may be held constant while the time is varied to change the beam dose.

Additionally, other GCIB properties may be varied to adjust the film thickness, and other film properties such as the surface roughness, including, but not limited to, gas flow rate, stagnation pressure, cluster size, or gas nozzle design (such as nozzle throat diameter, nozzle length, and/or nozzle divergent section half-angle). Furthermore, other film properties may be varied by adjusting the GCIB properties including, but not limited to, film density, film quality, etc.

The deposition of the first material layer may include depositing a SiNₓ, SiCₓ, SiCₓN_{y}, BNₓ, BSiₓN_{y}, Ge, SiGe(B), or SiC(P) film on a substrate or layer on a substrate. According to embodiments of the invention, the pressurized gas mixture may thus comprise a nitrogen-containing gas, a carbon-containing gas, a boron-containing gas, a silicon-containing gas, a phosphorous-containing gas, a sulfur-containing gas, a hydrogen-containing gas, a silicon-containing gas, or a germanium-containing gas, or a combination of two or more thereof.

When depositing silicon, a substrate may be irradiated by a GCIB formed from a pressurized gas mixture having a silicon-containing gas. For example, the pressurized gas mixture may comprise silane (SiH₄). In another example, the pressurized gas mixture may comprise disilane (Si₂H₆), dichlorosilane (SiH₂Cl₂), trichlorosilane (SiCl₃H), diethylsilane (C₄H₁₂Si), trimethylsilane (C₃H₁₀Si), silicon tetrachloride (SiCl₄), silicon tetrafluoride (SiF₄), or a combination of two or more thereof.

When depositing a nitride such as SiNₓ, a substrate may be irradiated by a GCIB formed from a pressurized gas mixture having a silicon-containing gas and a nitrogen-containing gas. For example, the pressurized gas mixture may comprise silane (SiH₄) and N₂. In another example, the pressurized gas mixture may comprise N₂, NO, NO₂, N₂O, or NH₃, or any combination of two or more thereof.

When depositing a carbide such as SiCₓ, a substrate may be irradiated by a GCIB formed from a pressurized gas mixture having a silicon-containing gas and a carbon-containing gas. For example, the pressurized gas mixture may comprise silane (SiH₄) and CH₄. Additionally, for example, the pressurized gas mixture may comprise silane (SiH₄) and methylsilane (H₃C-SiH₃). Furthermore, for example, the pressurized gas mixture may comprise a silicon-containing gas and CH₄ (or more generally a hydrocarbon gas, i.e., CₓH_{y}), CO, or CO₂, or any combination of two or more thereof. Further yet, for example, the pressurized gas mixture may comprise an alkyl silane, an alkane silane, an alkene silane, or an alkyne silane, or any combination of two or more thereof. Additionally, for example, the pressurized gas may include silane, methylsilane (H₃C—SiH₃), dimethylsilane (H₃C—SiH₂—CH₃), trimethylsilane ((CH₃)₃—SiH), or tetramethylsilane ((CH₃)₄—Si), or any combination of two or more thereof. When forming a carbonitride such as SiCₓN_{y}, the pressurized gas may further comprise a nitrogen-containing gas. For example, the nitrogen-containing gas may include N₂, NH₃, NF₃, NO, N₂O, or NO₂, or a combination of two or more thereof. The addition of a nitrogen-containing gas may permit forming a silicon carbonitride film (SiCN).

When depositing a nitride such as BNₓ, a substrate may be irradiated by a GCIB formed from a pressurized gas mixture having a boron-containing gas and a nitrogen-containing gas. For example, the pressurized gas mixture may comprise diborane (B₂H₆) and N₂. In another example, the pressurized gas mixture may comprise N₂, NO, NO₂, N₂O, or NH₃, or any combination of two or more thereof.

When depositing a nitride such as BSiₓN_{y}, a substrate may be irradiated by a GCIB formed from a pressurized gas mixture having a silicon-containing gas, boron-containing gas, and a nitrogen-containing gas. For example, the pressurized gas mixture may comprise silane (SiH₄), diborane (B₂H₆) and N₂. In another example, the pressurized gas mixture may comprise N₂, NO, NO₂, N₂O, or NH₃, or any combination of two or more thereof.

In any one of the above examples, the pressurized gas mixture may comprise an optional inert gas. The optional inert gas may comprise a noble gas.

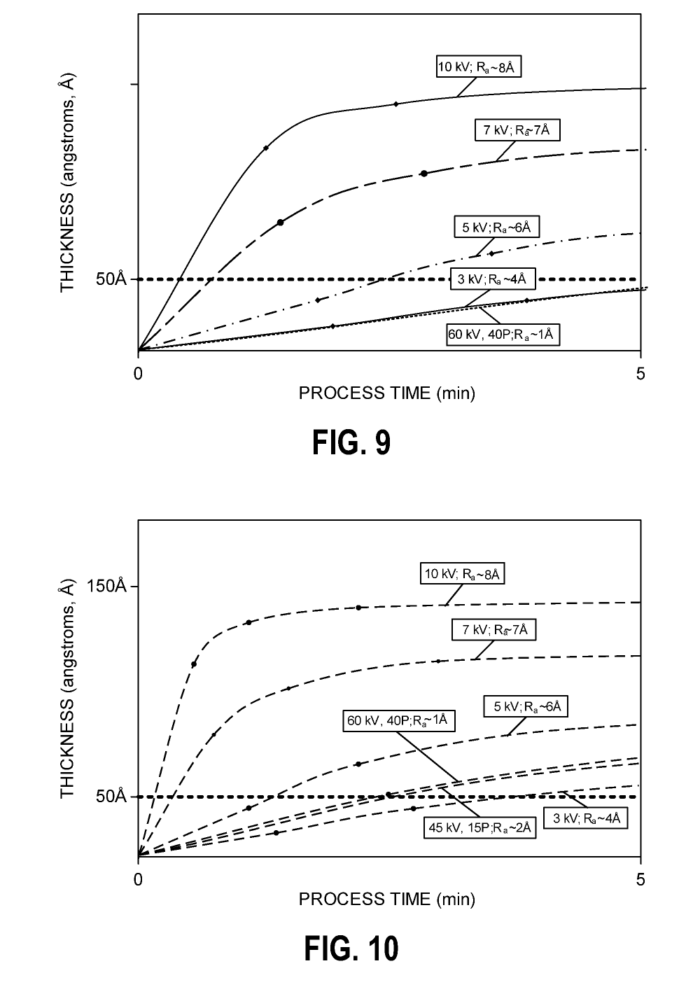

According to an example, Si is deposited on a substrate by irradiating the substrate with a GCIB formed from a pressurized gas mixture containing SiH₄. Film thickness (measured in angstrom, Å) and surface roughness (measured in angstroms, Å) are collected and provided in FIG. 8. The data provided in FIG. 8 is obtained using a GCIB processing system having a five (5)-electrode beam line. For example, the set of suitably biased high voltage electrodes resemble the electrode system illustrated in FIGS. 2 through 4.

As shown in FIG. 8, the thickness increases as a function of process time (or beam dose). The deposition rate (or slope) depends on the beam acceleration potential. Additionally, the surface roughness (average roughness, Rₐ) depends on the beam acceleration potential. As the beam acceleration is increased, the surface roughness is increased. Conversely, as the beam acceleration is decreased, the surface roughness is decreased. As shown in FIG. 8, when the beam acceleration potential is reduced to below about 5 kV, ultra-thin films of moderate surface roughness may be achieved. For example, when the beam acceleration potential is at or below about 3 kV, sub-50 Å films having a surface roughness at or below 4 Å may be achieved.

Referring again to FIG. 7, in 720, a second material layer is grown from at least a surface portion of the first material layer by introducing the second atomic constituent (or constituents) using a second GCIB to react with the first constituent(s). The substrate may be disposed in a second GCIB processing system (e.g., second GCIB processing system 440). The second GCIB processing system can by any of the GCIB processing systems (100, 100′, 100″) described above in FIGS. 2, 3, or 4, or any combination thereof. The substrate can be positioned on a substrate holder and may be securely held by the substrate holder. The temperature of the substrate may or may not be controlled. For example, the substrate may be heated or cooled during a film forming process. The environment surrounding the substrate is maintained at a reduced pressure. A second GCIB is generated in the reduced-pressure environment. The second GCIB can be generated from a pressurized gas mixture having a film forming composition comprising a second atomic constituent (or constituents) and an optional inert gas. A beam acceleration potential and a beam dose can be selected. The beam acceleration potential and the beam dose can be selected to achieve a desired thickness of the grown thin film, and to achieve a desired surface roughness of an upper surface of the grown thin film.

Additionally, other GCIB properties may be varied to adjust the film thickness, and other film properties such as the surface roughness, including, but not limited to, gas flow rate, stagnation pressure, cluster size, or gas nozzle design (such as nozzle throat diameter, nozzle length, and/or nozzle divergent section half-angle). Furthermore, other film properties may be varied by adjusting the GCIB properties including, but not limited to, film density, film quality, etc.

When growing an oxide such as SiOₓ, a substrate having a deposited first material layer of silicon or a silicon-containing material may be irradiated by a GCIB formed from a pressurized gas mixture having an oxygen-containing gas. For example, the pressurized gas mixture may comprise O₂. In another example, the pressurized gas mixture may comprise O₂, NO, NO₂, N₂O, CO, or CO₂, or any combination of two or more thereof.

When growing a nitride such as SiNₓ, a substrate having a deposited first material layer of silicon or a silicon-containing material may be irradiated by a GCIB formed from a pressurized gas mixture having a nitrogen-containing gas. For example, the pressurized gas mixture may comprise N₂. In another example, the pressurized gas mixture may comprise N₂, NO, NO₂, N₂O, or NH₃, or any combination of two or more thereof.

When growing a carbide such as SiCₓ, a substrate having a deposited first material layer of silicon or a silicon-containing material, may be irradiated by a GCIB formed from a pressurized gas mixture having a carbon-containing gas. For example, the pressurized gas mixture may comprise CH₄. In another example, the pressurized gas mixture may comprise CH₄ (or more generally a hydrocarbon gas, i.e., CₓH_{y}), CO, or CO₂, or any combination of two or more thereof.

When growing an oxynitride such as SiOₓN_{y}, a substrate having a deposited first material layer of silicon or a silicon-containing material may be irradiated by a GCIB formed from a pressurized gas mixture having an oxygen-containing gas and a nitrogen-containing gas. For example, the pressurized gas mixture may comprise O₂ and N₂, NO, NO₂, or N₂O, or any combination of two or more thereof.

When growing a carbonitride such as SiCₓN_{y}, a substrate having a deposited first material layer of silicon or a silicon-containing material may be irradiated by a GCIB formed from a pressurized gas mixture having a carbon-containing gas and a nitrogen-containing gas. For example, the pressurized gas mixture may comprise CH₄ and N₂.

When forming a germanide such as SiGe, a substrate having a deposited first material layer of silicon or a silicon-containing material may be irradiated by a GCIB formed from a pressurized gas mixture having a germanium-containing gas. For example, the pressurized gas mixture may comprise GeH₄ or Ge₂H₆, or both.

In any one of the above examples, the pressurized gas mixture may comprise an optional inert gas. The optional inert gas may comprise a noble gas.

According to another example, SiO₂ is grown on a first material layer comprising silicon by irradiating the substrate with a GCIB formed from a pressurized gas mixture containing O₂. Film thickness (measured in angstroms, Å) and surface roughness (measured in angstrom, Å) are collected and provided in FIG. 9. The data provided in FIG. 9 is obtained using a GCIB processing system having a three (3)-electrode beam line. For example, the set of suitably biased high voltage electrodes, illustrated in FIGS. 2 through 4, include a three electrode arrangement having an extraction electrode (positively biased), a suppression electrode (negatively biased) and a ground electrode.

The film thickness of the grown film is provided as a function of the beam acceleration potential (measured in kV) (i.e., beam energy) and process time (measured in minutes, min) (i.e., beam dose). In each case, the thickness increases as a function of process time (or beam dose) until it eventually saturates. The maximum thickness and the elapsed process time associated with substantially achieving the maximum thickness depend on the beam acceleration potential. As the beam acceleration is increased, the maximum thickness is increased and the time to achieve the maximum thickness is decreased. Conversely, as the beam acceleration is decreased, the maximum thickness is decreased and the time to achieve the maximum thickness is increased.

Additionally, the surface roughness (average roughness, Rₐ) depends on the beam acceleration potential. As the beam acceleration is increased, the surface roughness is increased. Conversely, as the beam acceleration is decreased, the surface roughness is decreased.

As shown in FIG. 9, when the beam acceleration potential is reduced to below about 5 kV, ultra-thin films of moderate surface roughness may be achieved. For example, when the beam acceleration potential is at or below about 3 kV, sub-50 Å films having a surface roughness at or below 4 Å may be achieved.

Furthermore, for a given film thickness, the surface roughness may be decreased by modifying the beam energy distribution function. With the exception of a few data sets, each data set is acquired using a GCIB processing system without modification of the beam energy distribution function, e.g., without a pressure cell having an increased pressure region through which the GCIB passes. In the case of the exceptions, the beam energy distribution function of the GCIB is modified by directing the GCIB along a GCIB path through an increased pressure. In one case, the path length (d) of the pressure cell is set to d˜23.3 cm and the pressure in the pressure cell is elevated by introducing a background gas. For example, in one case, the background gas is introduced at a flow rate of 15 sccm (standard cubic centimeters per minute) (“15P”) (or the pressure-distance integral is about 0.002 torr-cm) to the pressure cell or, in another case, the background gas is introduced at a flow rate of 40 sccm (“40P”) (or the pressure-distance integral is about 0.005 torr-cm) to the pressure cell.

As shown in FIG. 9, the modification of the beam energy distribution function may be used to reduce the surface roughness while maintaining about the same film thickness (by increasing the beam acceleration potential). For example, when the beam acceleration is increased to 60 kV and the pressure in the pressure cell is set to “40P”, the resultant film thickness as a function of process time nearly coincides with the film thickness measured for a 3 kV beam acceleration potential without the use of the pressure cell. However, with the use of the pressure cell, the surface roughness is reduced from about 4 Å to about 1 Å.

According to another example, SiO₂ is grown on a silicon substrate by irradiating the substrate with a GCIB formed from a pressurized gas mixture containing O₂. Film thickness (measured in angstrom, Å) and surface roughness (measured in angstroms, Å) are collected and provided in FIG. 10. The data provided in FIG. 10 is similar to that of FIG. 9; however, the data is obtained using a GCIB processing system having a five (5)-electrode beam line. For example, the set of suitably biased high voltage electrodes resemble the electrode system illustrated in FIGS. 2 through 4.

As shown in FIG. 10, the thickness increases as a function of process time (or beam dose) until it eventually saturates. The maximum thickness and the elapsed process time associated with substantially achieving the maximum thickness depend on the beam acceleration potential. Additionally, the surface roughness (average roughness, Rₐ) depends on the beam acceleration potential. As the beam acceleration is increased, the surface roughness is increased. Conversely, as the beam acceleration is decreased, the surface roughness is decreased.

Also, as shown in FIG. 10, the modification of the beam energy distribution function may be used to reduce the surface roughness while maintaining about the same film thickness (by increasing the beam acceleration potential). For example, when the beam acceleration is increased to 60 kV and the pressure in the pressure cell is set to “40P”, an ultra-thin film may be grown having a thickness less than about 50 Å and a surface roughness of about 1 Å.

The first material layer may be deposited with a first thickness, and the second material layer may be grown using the first material layer to have a second thickness less than or equal to the first thickness. Additionally, the depositing and growing of the first material layer and the second material layer, respectively, may be repeated in order to achieve a desired thickness for the thin film. Furthermore, a third material layer may be grown from at least asurface portion of the second material layer by introducing a third atomic constituent using a third GCIB, the third material layer comprising a reaction product of said first, second and third atomic constituents.

Following the growth of the second material layer, the second material layer may be diffused further into the first material layer. For example, the diffusion of the second material layer into the first material layer may be achieved using an annealing process to be described below.

The method described above may be used to form a silicon-containing oxide film. For example, a layer of silicon-containing material is deposited on a substrate using a first GCIB. Thereafter, the layer of silicon-containing material is oxidized on the substrate using a second GCIB.

Prior to depositing the first material layer, a surface of the substrate may be pre-treated to remove residue or other contaminants. The pre-treatment step may include a cleaning or pre-cleaning step. Additionally, the pre-treatment step may include a dry or wet treatment process. Furthermore, the pre-treatment step may include a plasma or non-plasma treatment process. Further yet, the pre-treatment step may be performed in-situ or ex-situ to subsequent steps.

Furthermore, following the growth of the second material layer, the substrate may be annealed. The first and/or second material layers on the substrate may be annealed via a thermal treatment, wherein the temperature of the substrate is elevated to a material-specific temperature and held at that elevated temperature for a period of time. The temperature and the time for the annealing process may be adjusted in order to vary film properties. For example, the temperature of the film may be elevated to a value greater than about 800 degrees C. Additionally, for example, the temperature of the film may be elevated to a value greater than about 850 degrees C. Additionally yet, for example, the temperature of the film may be elevated to a value greater than about 900 degrees C. Furthermore, for example, the time for the annealing process may be greater than about 1 millisecond. The annealing process may be performed at atmospheric pressure or reduced pressure. Additionally, the annealing process may be performed with or without an inert gas atmosphere. Furthermore, the annealing process may be performed in a furnace, a rapid thermal annealing (RTP) system, a flash lamp annealing system, or a laser annealing system.

Amorphous films having a variety of material compositions can be produced, and anisotropic (or directional) growth can be achieved using one or more GCIBs. Further, as the GCIB energy (or beam acceleration potential) is increased, the anisotropy (or directionality) may be increased (i.e., more material is deposited and/or grown on substantially horizontal surfaces while less material is grown on substantially vertical surfaces). Therefore, by adjusting the beam acceleration potential, an amount of the thin film deposited and/or grown on the one or more first surfaces relative to another amount of the thin film deposited and/or grown on the one or more second surfaces may be varied. Once the amorphous film is formed, it may be subjected to one or more thermal cycles (e.g., elevation of temperature) in order to crystallize the film.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

What is claimed is:

1. A method of forming a thin film on a substrate, comprising:
depositing a first material layer on a substrate to a first thickness using a first gas cluster ion beam (GCIB), said first material layer comprising a first atomic constituent; and
growing a second material layer from at least a surface portion of said first material layer by introducing a second atomic constituent using a second GCIB, said second material layer comprising a reaction product of said first and second atomic constituents.

2. The method of claim 1, further comprising:
growing a third material layer from at least a surface portion of said second material layer by introducing a third atomic constituent using a third GCIB, said third material layer comprising a reaction product of said first, second and third atomic constituents.

3. The method of claim 1, further comprising:
repeating said depositing and said growing to achieve a desired thickness for said thin film.

4. The method of claim 1, wherein said second material layer comprises a second thickness less than said first thickness.

5. The method of claim 4, further comprising:
diffusing said second atomic constituent further into said first material layer to increase said second thickness.

6. The method of claim 1, further comprising:
annealing said substrate to diffuse said second atomic constituent further into said first material layer.

7. The method of claim 1, wherein said second material layer is grown from all of said first material layer whereby said second material layer comprises a second thickness equal to said first thickness.

8. The method of claim 1, wherein said first atomic constituent is silicon, germanium, or boron whereby said depositing said first material layer comprises depositing a silicon-containing material, a germanium-containing material, or a boron-containing material.

9. The method of claim 1, wherein said first atomic constituent is silicon and said depositing said first material layer comprises depositing silicon, silicon nitride, silicon carbide, or silicon carbonitride.

10. The method of claim 1, wherein said introducing said second atomic constituent comprises introducing oxygen, nitrogen, carbon, or hydrogen, or any combination of two or more thereof.

11. The method of claim 1, wherein said depositing said first material layer comprises depositing silicon or silicon nitride, and wherein said growing said second material layer comprise oxidizing said first material layer by introducing oxygen.

12. The method of claim 1, wherein a thin film of SiOₓ is formed by depositing silicon on said substrate using said first GCIB, and growing SiOₓ by introducing oxygen using said second GCIB.

13. The method of claim 1, wherein said depositing said first material layer comprises:
providing said substrate in a reduced-pressure environment;
generating said first GCIB in said reduced-pressure environment from a pressurized gas mixture;
selecting a beam acceleration potential and a beam dose to achieve said first thickness of said first material layer;
accelerating said first GCIB according to said beam acceleration potential;
irradiating said accelerated GCIB onto at least a portion of said substrate according to said beam dose; and
depositing said first material layer on said at least a portion of said substrate to achieve said first thickness.

14. The method of said claim 12, wherein said pressurized gas mixture comprises silane, disilane, methylsilane, dimethylsilane, trimethylsilane, tetramethylsilane, ethylsilane, diethylsilane, triethylsilane, tetraethylsilane, silicon tetrachloride, silicon tetrafluoride, germane, digermane, dichlorogermane, trichlorogermane, diethylgermane, trimethylgermane, germane tetrachloride, germane tetrafluoride, boran, diborane, or boron trifluoride.

15. The method of claim 13, wherein said pressurized gas mixture further comprises H₂, O₂, CO, CO₂, N₂, NH₃, NF₃, NO, N₂O, NO₂, a noble gas, a hydrocarbon gas, or a hydrofluorocarbon gas, or any combination of two or more thereof.

16. The method of claim 1, wherein said depositing said first material layer compnses:
providing said substrate in a reduced-pressure environment;
generating said second GCIB in said reduced-pressure environment from a pressurized gas mixture;
selecting a beam acceleration potential and a beam dose to achieve a thickness of said second material layer;
accelerating said second GCIB according to said beam acceleration potential;
irradiating said accelerated second GCIB onto at least a portion of said substrate according to said beam dose; and
growing said first material layer on said at least a portion of said substrate to achieve said thickness.

17. The method of claim 16, wherein said pressurized gas mixture comprises oxygen and/or nitrogen, and an optional inert gas.

18. A method of forming a thin silicon-containing oxide film on a substrate, comprising:
depositing a layer of silicon-containing material on a substrate using a first gas cluster ion beam (GCIB); and
oxidizing said layer of silicon-containing material on said substrate by introducing oxygen using a second GCIB.

19. The method of claim 18, wherein said layer of silicon-containing material comprises a layer of silicon or a layer of silicon nitride.

20. The method of claim 18, further comprising:
repeating said depositing and said oxidizing to achieve a desired thickness for said thin silicon-containing oxide film.

21. The method of claim 18, further comprising:
annealing said thin silicon-containing oxide film.

22. A processing system for forming a thin film on a substrate, comprising:
a first GCIB processing system configured to generate a first GCIB containing a first atomic constituent from a first gas source and to deposit a first material layer on a substrate using said first GCIB;
a second GCIB processing system configured to generate a second GCIB containing a second atomic constituent from a second gas source and to grow a second material layer from at least a surface portion of said first material layer using said second GCIB; and
a substrate handling system coupled to said first GCIB processing system and said second GCIB processing system, and configured to transport one or more substrates to and from said first GCIB processing system and said second GCIB processing system.
